(19) United States
(12) Patent Application Publication
(10) Pub. No.: US 2008/0020579 A1
(43) Pub. Date: Jan. 24, 2008

(54) Method For Manufacturing A Membrane In A (111) Surface Of A (100) Silicon Wafer

(75) Inventor: Warner Jurrien Venstra, Leiden (NL)

Correspondence Address: AKERMAN SENTERFITT, P.O. BOX 3188, WEST PALM BEACH, FL, 33402-3188, US

(73) Assignee: Technische Universiteit Delft, Delft (NL)

(21) Appl. No.: 10/550,384

(22) PCT Filed: Mar. 22, 2004
(86) PCT No.: PCT/NL04/00197

§ 371 Date: Dec. 11, 2006

(30) Foreign Application Priority Data
Mar. 21, 2003 (NL) 1022995

(51) Int. Cl. H01L 21/311

(52) U.S. Cl. 438/702; 257/E21.231

(57) ABSTRACT

The invention relates to a method for the fabrication of a membrane oriented in a (111) plane of a (100) silicon wafer. To this end the method comprises the following steps: applying a mask to both sides of the wafer, wherein portions of the sides are covered by the mask; and the at least partial removal by etching away silicon material from the portions of the two sides of the wafer that are not covered. This method is characterised in that the etching step substantially removes the silicon material forming recesses in the two surfaces of the wafer, such that the walls of the recesses are formed by (111) planes, and in that not covered portions at both sides of the wafer are aligned in relation to one another such that a (111) plane is formed and the distance d between said two planes is less than the thickness of the silicon wafer, so as to form a membrane in the (111) plane having a thickness d. Such a membrane has many application possibilities in the field of MEMS, for example by dividing the membrane into individual cantilevers.

The invention, relates to a method for the fabrication of a membrane oriented in a (111) plane of a (100) silicon wafer, as well as to membranes fabricated by this method and their applications. The method mentioned in the preamble comprises the steps of:
applying a mask to both sides of the wafer, wherein portions of the sides are covered by the mask; and
the at least partial removal by etching away silicon material from the portions of the two sides of the wafer that are not covered.

The invention also relates to a membrane fabricated by a method according to the invention.

Finally, the invention relates to the application of the membrane obtained by the method according to the invention.

In accordance with the invention the term “membrane” refers to a plate-like projection oriented in a (111) plane of a silicon wafer having a thickness d that is substantially smaller than a length 1 and a width b of the plate-like projection. The membrane is at least at one side Z attached to the body of the silicon wafer.

The term “cantilever” mentioned later in this specification refers to a portion of the membrane obtained by dividing said membrane in one direction substantially perpendicular to the side Z and along the length 1. Thus the cantilevers will have a length 1 and a thickness d. The width of the cantilever depends on the distance at which the divisions are made.

When reference is made in the present specification to an “etching step” or an “etching treatment” this means, as generally known in the semiconductor technology, that a masking layer is applied on a silicon surface, partially covering the silicon surface. The silicon of the silicon wafer that is not covered will then be at least partly removed during the etching treatment. This forms a recess in the surface of the silicon. When the desired amount of silicon material has been etched away, the treatment will be stopped and the masking layer removed. These steps, as well as the etching agents to be used, such as KOH, TMAH, EDP and others, and the concentrations to be used, are generally known.

The method mentioned in the preamble is known in the art. The method is used in particular in the semiconductor industry.

It is the object of the invention to provide a method as mentioned above, which can conveniently be used for the fabrication of micromechanical constructions. A particular object of the invention is to provide an improved method, that is convenient to use for the fabrication of membranes, that can be processed further so as to render them suitable as, for example, a filter for liquids.

A specific object of the invention is to provide such a method by which a membrane can be fabricated that can be used as sensor.

Further objectives will become clear from the following description.

In order to achieve at least one of the above-mentioned objects, the invention provides a method as mentioned in the preamble, which is characterised by the method described in claim 1.

Particular preferred embodiments are described in the subclaims.

A particular preference is afforded by a method wherein a recess in a first side extends through to the masking layer on the second side. Removal of the masking layer will then provide an opening through the silicon wafer.

Preferably the membrane can be fabricated in a predetermined thickness. In accordance with the preferred embodiment, the method is therefore characterised in that the thickness d is measured and the etching step is continued to etch the (111) planes until a desired thickness d is attained.

As already mentioned before, after completion of the etching step it is especially preferable to remove the masking layer.

The membrane formed may be coated completely or partly, for example in a predetermined pattern, using a material that exhibits different etching behaviour than silicon, whereafter the silicon material is at least partly etched away. In particular, the material may be applied at least over a portion of the surface of the silicon membrane. The material may be chosen especially from silicon nitride, silicon oxide or silicon carbide. It is also possible to make three-dimensional mechanical structures from materials other than silicon, such as silicon nitride, silicon oxide or silicon carbide, that have different mechanical properties (rigidity, strength, hardness, etc.). It is also possible to apply a conductive layer (in practice often aluminium). In this way, for example a heating element can be formed, in which case the form of the layer of material applied extends from a first connection point to a second connection point in the shape of a heating element, and is connected at the two connecting points to a power source.

A particular embodiment of the invention relates to a method wherein the openings to be formed in the membrane extend from the end of the membrane to a point where the membrane is connected with the main body of the wafer. It is especially preferred for at least two parallel linear openings to be formed, oriented substantially perpendicular in relation to the line where the formed membrane is attached to the wafer, so as to form at least one cantilever. The width of such cantilevers may be determined by the distance between the linear openings in the membrane. The thickness d of the cantilever will be equal to the thickness d of the membrane. The length 1 of the cantilever will be determined by the length of the linear openings.

Especially such membranes afford unforeseen application possibilities for the constructions formed by the method according to the invention. Hereinbelow these applications will be described further.

According to an especially suitable embodiment, the membrane according to the invention may be used as filter. For this purpose openings are formed in the membrane. These openings may be provided in various ways, for example, by radiation with a high-energy source. An example of this is ion etching. Another possibility is the use of a dry-etching treatment, preferably a plasma etching treatment. This allows the focused application of openings in the membrane. The person skilled in the art is well aware of the fact that it is in some cases necessary to apply a masking layer on the surface of the membrane.

The openings may have a predetermined diameter. This makes very selective filtering of, for example, liquids possible.

Another possibility entails the membrane being fabricated in such a way that it is at one side Z attached to the main body of the wafer while being free at the other side. Thus substantially plate-like projection will be formed that are attached at one side to the main body of the wafer. Such a membrane can conveniently be provided with linear openings extending from the free end of the membrane toward the side Z. The result is the formation of so-called cantilevers. By providing such linear openings at regular intervals, a predetermined number of cantilevers will be formed parallel to one another.

Although it is mentioned that it is preferred for the linear openings to be provided substantially perpendicularly to the side Z, it is of course also possible to provide the linear openings at an angle to the side Z. The width of the linear openings may vary within a wide range. The openings may also have other shapes, such as for example, halter-shape, triangular and the like.

Cantilevers as mentioned above may be used for all kinds of applications. For example, it is possible to apply a reflecting layer on one surface of such a cantilever. The silicon surface itself may possibly serve as reflecting layer. By providing the other surface with a sensor layer or an actuator layer comprised of a suitable compound, it becomes possible to cause the cantilever to bend slightly in a predetermined manner. This may occur, for example, because the sensor layer reacts with a compound present near the sensor layer causing the sensor layer to expand or shrink. If the sensor layer is sufficiently strongly bonded with the silicon surface of the cantilever, it will be caused to bend. If an actuator layer is suitably bonded to the silicon material of the cantilever it is possible, for example by applying a voltage over the actuator layer, to cause the cantilever to bend. Similarly, other materials that react, for example, to temperature may also be used in such a system. A light beam falling on the reflecting surface at the other side, said light beam will, if said cantilever is bent, be deflected to another position. This position change can be detected by suitable sensors, so that the change in state can be detected.

Optionally the sensor layer or the actuator layer may be used as reflecting surface.

Such a system may, for example, be suitable for detecting particular compounds in a liquid. In a corresponding manner such a system may be used for the detection of temperature changes or the like.

If on one side of the cantilever an actuator layer is applied that can be controlled by a regulated voltage, a light beam can be deflected in a previously determined manner. Such a system is suitable for many uses involving light beams to be deflected or reflected.

In principle any electromagnetic radiation that can be reflected can be used in such a system.

Another suitable application of the membranes according to the invention is provided by positioning two membranes in a V-shape such that the ends of the two membranes that are at one side connected to the main body of the wafer point towards a mutual point of intersection, and their free ends are placed a distance from one another. In such an embodiment, for example, a glass fibre may be positioned in the V formed by the two membranes. By providing at least one of the two membranes with an actuator layer, the same may be positioned such that the glass fibre assumes a desired position. This makes it possible to bring glass fibres into alignment with one another. A further description will follow by way of the figures.

The membrane according to the invention can very suitably be used as so-called scanning element for a scanning electron microscope, a scanning probe microscope, or a friction force microscope. The silicon membrane's dimensions can be defined very precisely, and may be of a size such as to be useful as scanning elements.

Positioned in a V-shape as mentioned above, such membranes may also be used for griping small objects. For example, two membranes may be positioned in a V-shape, wherein at least one surface of at least one of these is provided with an actuator layer, so that the distance between the two cantilevers can be increased by appropriately actuating this cantilever. A chosen object to be gripped can be positioned between the two cantilevers, whereafter the actuation can be cancelled, causing the distance between the ends of the two cantilevers to be decreased. The object positioned in-between is thereby suitably gripped.

According to a further embodiment it is possible to move the gripped object and to release it at another position by actuating at least one of the cantilevers, and releasing the gripped object.

If the membrane according to the invention is used as filter, at least one opening will be provided in the membrane. This opening will extend through the entire membrane. Due to the fact that at both sides of the wafer V-shaped openings are formed, separated from each other only by the membrane, there are also fluid conduction channels created. By sealing both surfaces of the wafer, the two fluid conduction channels will be in communication only by means of the at least one opening in the membrane. The maximum flow rate of the fluid can be regulated by varying the number of openings. By suitably adjusting the diameter of the openings it is possible to regulate the degree of filtration.

The thus formed construction is suitable for repeated application, so that in a fabrication process a filter can be made comprising different stages and respective opening sizes.

Further preferred embodiments and suitable applications are mentioned in the subclaims, and all of these pertain to the present invention. The invention is especially suitable for application in a fuel cell element.

Hereinbelow the invention will be further elucidated with reference to a number of figures.

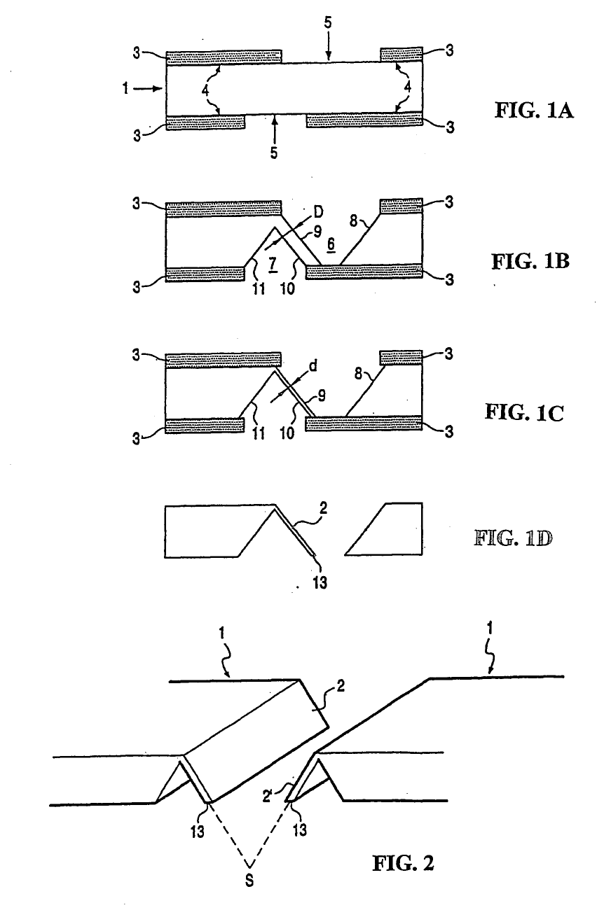

FIG. 1 shows the fabrication of a membrane according to the invention in four steps.

FIG. 2 shows two membranes in perspective.

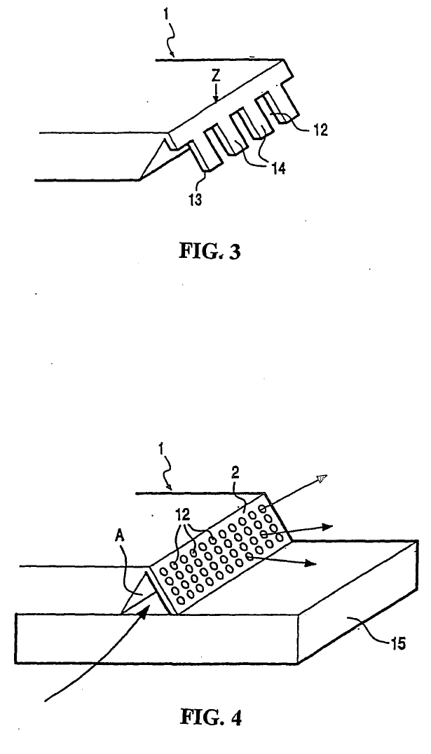

FIG. 3 shows a membrane, which by means of linear openings is divided into cantilevers.

FIG. 4 shows a membrane according to the invention, which is used in a filter.

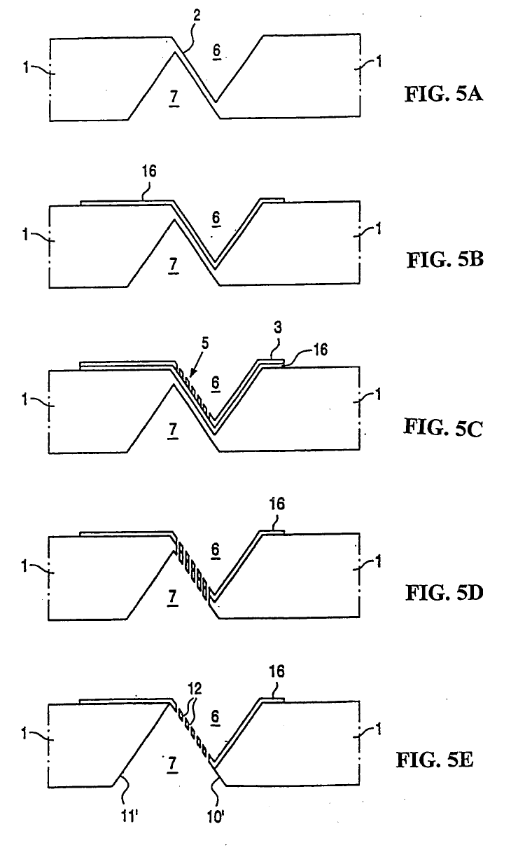

FIG. 5 shows a preferred embodiment of the method for the fabrication of the membrane in five steps.

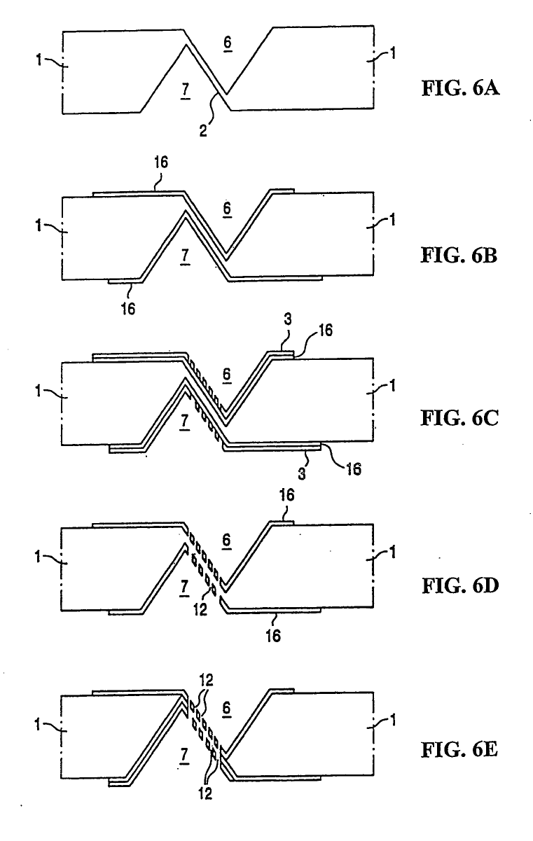

FIG. 6 shows a variant of the embodiment according to FIG. 5.

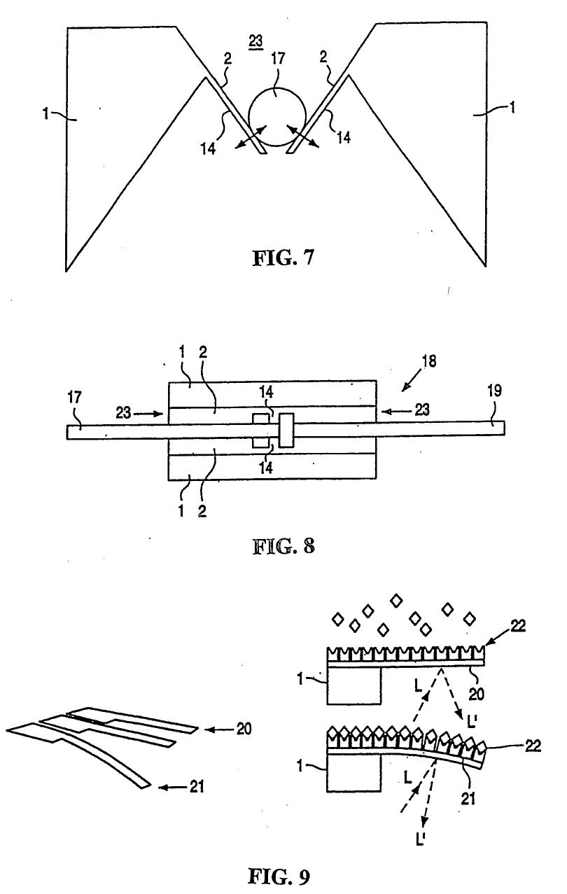

FIG. 7 shows a schematic cross-section through a fibre-positioning means.

FIG. 8 shows a top view of a fibre positioning means.

FIG. 9 shows a perspective, schematic illustration of an application of a cantilever as mirror.

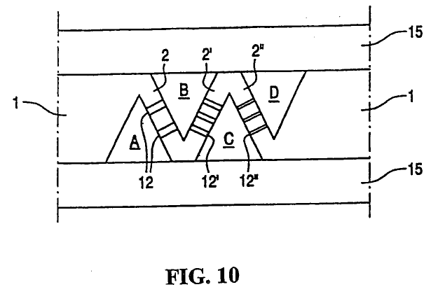

FIG. 10 shows a cascade filter.

In the various figures similar elements are identified with identical reference numerals.

FIG. 1 shows a number of steps for the fabrication of a membrane 2 according to the invention. In a first step, FIG. 1A, a masking layer 3 is applied on two sides of a silicon wafer 1, leaving portions 5 of the silicon surface free. In a second step, FIG. 1B, a portion of the silicon is etched away in a quick-etching step, exposing the so-called (111) planes 8, 9, 10, 11. During this step a membrane 2 having a thickness D is already formed. In a subsequent step, FIG. 1C, a slow-etching step is carried out. As in this stage only the (111) planes 8, 9, 10, 11 are exposed, the etching treatment will be slow. This allows a precise regulation of the thickness of the membrane 2. This treatment is carried out until a desired thickness d is obtained. Finally, as shown in FIG. 1D, the masking layers 3 are removed, providing the membrane 2.

FIG. 2 shows a much simplified perspective view of two membranes 2, 2′, which are obtained in accordance with the embodiment of FIG. 1. The two ends 13 of the membranes 2, 2′ are directed at a mutual point of intersection S, located in a plane below the plane of the wafer 1.

FIG. 3 shows a perspective view of a single membrane 2 that may be obtained by the method shown in FIG. 1. A number of linear openings 12 are formed in the membrane 2. This creates cantilevers 14, all of which are attached at one side Z of the originally formed membrane 2 to the main body of the wafer 1. Such cantilevers may also be fabricated in accordance with the method described by way of the FIGS. 5A to 5E.

FIG. 4 shows a similar embodiment wherein the openings 12, however, are not linear but are substantially round openings 12. Because the lower side of the wafer is provided with a sealing body 15, a fluid can be introduced into the cavity A. The liquid can then only be discharged through the openings 12 in the membrane 2. Any material in the liquid larger than the diameter of the openings 12 will be retained in the cavity A.

FIG. 5 shows a further embodiment of the method according to the invention. Starting point is an already-formed membrane 2, as shown in FIG. 5A.

Subsequently a material layer 16 is applied on one side covering at least a portion of the surface of the silicon wafer 1 and also the surface of the V-shaped recess 6. Such a material will preferably be a material exhibiting a different etching behaviour to that of the silicon used for the wafer.

The material for forming the layer 16 may be any material other than the silicon used for the wafer, such as carbides, oxides and nitrides, in particular silicon carbide, silicon oxide and silicon nitride, but also other pure elements, such as metals including gold, and also synthetic materials and the like.

Subsequently, a masking layer 3 is provided on the material 16 in a predetermined pattern. This is clearly shown in FIG. 5C.

In a following step, an etching treatment is carried out, in which material present under the portions 5 that are not covered by the masking layer 3, is removed. Such a treatment may be carried out for a desired period of time, so as to create through-openings 12. When the etching treatment has been carried out in the desired manner, the masking layer 3 may be removed, as shown in FIG. 5D.

Subsequently, an etching treatment may be carried out for the removal of the remaining silicon portions under the applied material layer 16. This etching treatment will be performed quickly because the etching solution may affect other surfaces than those oriented in the (111) plane. After completion of said etching treatment a product will be obtained as shown in FIG. 5E, of which the exposed silicon surfaces 10′, 11′ will be oriented in the (111) planes.

Optionally it is possible to cover the portions of the main surface of the silicon wafer that during the silicon etching treatment are not to be removed, with a masking layer. However, this is not further shown in the figures.

An alternative embodiment of the method shown in FIG. 5 is depicted in FIG. 6. The difference between this embodiment and the method according to FIG. 5 is that the lower side of the wafer 1 is now also provided with a material layer 16. This material layer also is provided with a masking layer 3 in a predetermined pattern. This pattern may be substantially aligned with the pattern provided at the upper side. However, this is not obligatory.

By carrying out the same steps described in FIG. 5, a product can be obtained as shown in FIG. 5E.

The steps shown in the FIGS. 5A to 5E may be carried out in a corresponding manner for the fabrication of cantilevers, as shown in a different embodiment in FIG. 3.

It is especially preferred for the etching treatment for the removal of material layers at the places not covered by the masking layer 3, to be carried out such that no through-openings through the silicon membrane layer 2 are formed. The etching treatment must be carried out only far enough to reach the silicon layer. For such a case different masking patterns may be created on both sides. The intermediate layer of silicon may be removed in a subsequent silicon etching treatment, wherein two differently formed layers of material are formed in a desired pattern. This makes it possible, for example, to form two layers of material, each providing a filter pattern whose openings in the one layer of material are larger than the openings in the other layer of material. This makes it possible in particular, to filter out contaminants or other particulate material of a desired size between the two layers of material.

FIG. 7 shows an embodiment for positioning a glass fibre 17. A glass fibre 17 is positioned on two separate membranes. Such membranes may be formed, for example, as cantilevers 14. By providing at least one of these cantilevers 14 with an actuation layer it is possible to position the glass fibre 17 as desired.

A positioning means 18 is further shown in a top view in FIG. 8. A first glass fibre 19 is fixedly positioned in the V-shaped groove 23. Another glass fibre 17 is positioned on two cantilevers 14 of which at least one can be actuated. By positioning the at least one cantilever 14 independently of the other in a suitable manner, the relative positioning of the second glass fibre 17 in relation to the first, fixed glass fibre 19 can be carried out such that it is aligned exactly in the extended direction of the fixed glass fibre 19. After that the second glass fibre 17 can be fixed.

FIG. 9 finally shows an embodiment wherein the cantilever according to the invention functions as mirror. A first cantilever 20 is in rest. A second cantilever 21 is in a bent condition, which may be effected, for example, by activating an actuating layer 22.

Other possibilities consist of cantilevers that are provided with a sensor layer reacting specifically with a certain compound contained, for example, in a fluid. When said sensor-layer bonds with the intended compound a deflection (22) of the cantilever may be produced. A light beam L directed at a surface of the cantilever 21 will therefore deflect at a different angle L′ than when the cantilever 20 is in the starting position. This deflection can be suitably detected by means of known devices.

FIG. 10 shows a cascade filter. Herein covering bodies 15 are provided at two sides of the wafer 1. A liquid to be filtered containing contaminants of different sizes is introduced into the cavity A and via the openings 12 in the first membrane 2 conducted into the cavity B. From there the liquid is conducted through the openings 12′ in the membrane 2′ into the cavity C. Finally, the liquid is conducted through the openings 12″ in the membrane 2″ into the cavity D. The openings 12, 12′ and 12″ have decreasing diameters. Via the cavities A, B, C and D the substances in the liquid retained by the respective membranes 2, 2′, 2″, can be discharged (not shown).

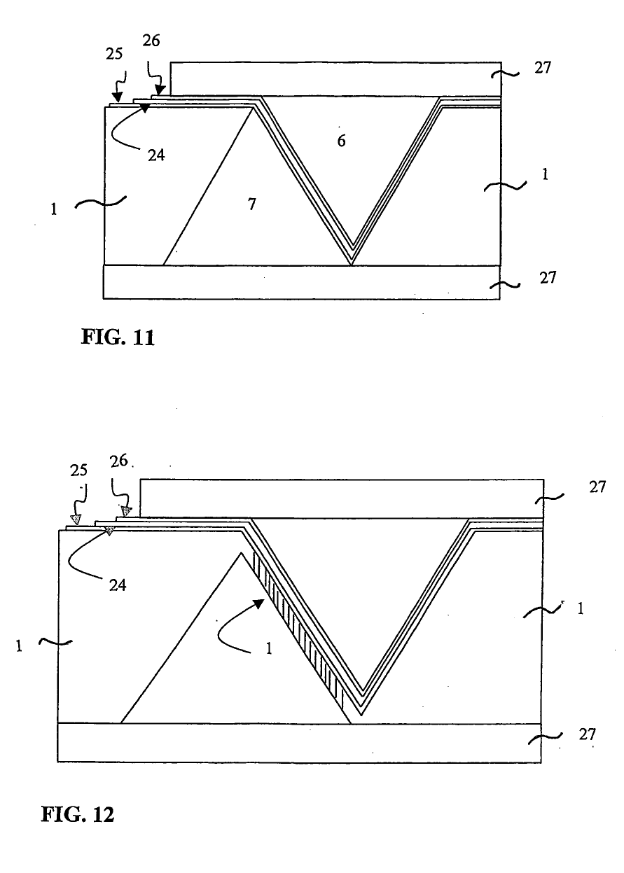

A new concept for the fabrication of a fuel cell element by a significantly simplified production process than in use at present, is shown in FIG. 11. The two compartments 6, 7 are formed in one substrate 1 and are located at both sides of electrodes 25, 26 (anode and cathode). In addition, the present method affords a very large active surface per unit area (high fill factor). Moreover, only one wafer 1 needs to be treated. During assembly, no demands regarding the alignment of the wafers need to be taken into consideration.

The FIGS. 11 and 12 show a cross-section of embodiments of a single fuel cell element according to the present invention. The fuel and the oxidant are conducted through the V-shaped channels 6 and 7 formed by anisotropic etching at the upper and lower side of the wafer 1. The V-shaped channels 6, 7 may optionally also comprise integrated thermal heating elements, for example, in the form of a conductive wire provided on a (111) plane.

An intermediate layer 24, or electrolyte 24, may consist of a solid oxide, a solid polymer, a proton exchange membrane. Alternatively, a catalytic layer 24 may separate the electrodes 25, 26 (anode and cathode).

More specifically, FIG. 11 shows an embodiment of a fuel cell wherein the silicon membrane 1 is completely etched away in order to form two channels 6, 7. The membrane 1 in the (111) orientation is formed by two perforated electrodes 25, 26, one intermediate electrolyte layer 24 and optionally extra layers (not shown the figure).

FIG. 12 shows an embodiment for a fuel cell wherein the perforated silicon membrane 1 is still present (for example to reinforce the electrodes 25, 26 placed on the membrane 1). Part of the silicon membrane is still present, for example, to support the electrodes. For an operating fuel cell, the silicon membrane 1 needs to be perforated.

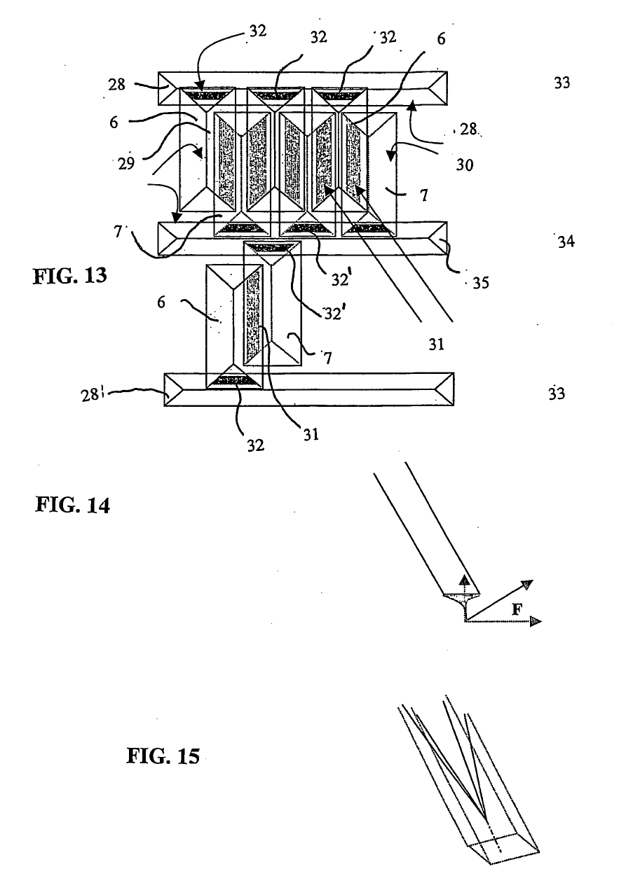

In practice the elements may be cascaded or in series, as shown in a top view in FIG. 13, in numerous ways. Heating elements may be integrated by depositing conductive electrodes on the (111) sides of the V-shaped channel, for example in a feed groove (top horizontal cavity in FIG. 13) or optionally, next to the reactive surfaces in the reactor compartments, indicated by hatching.

In FIG. 13 the possibility is shown of connecting fuel cell elements in order to increase the capacity or power (the cover plates 27 are not shown). The surfaces 29 are part of the cavities 6 at the upper side, the surfaces 30 are part of the cavities 7 at the lower side of the silicon wafer 1. The active surfaces 31 are indicated with hatching. At the dark surfaces 32, the (111) membranes are completely etched away, creating a passage of a V-groove 6 at the upper side to a V-groove 28 at the lower side. Via the portions 32′ where the (111) membranes are completely etched away, a passage from the groove 35 in the upper side to the groove 7 in the under side is created. Via the passages 32 and in the direction of the arrows 33, fuel or oxidant, respectively, reaches the active surfaces 31 of the membranes. Via the passages 32′ and in the direction of the arrow 34, oxidator or fuel from the groove 35 reaches the grooves 7. In the manner shown, a two-dimensional array may be constructed with serially- and parallel-connected fuel cells. In the manner described above it is also possible to form a cascade with the earlier described filter elements, by connecting the electrodes with one another in the appropriate manner.

The supply of fuel and oxidator will allow a reaction to take place which terminates, for example, when both or one of the two is/are completely used up, or earlier.

With the cantilevers (made of silicon or another material) a probe can be fabricated for example, for a scanning probe microscope (SPM), an AFM, or a friction force microscope. Because of its three-dimensional form, this is especially susceptible to lateral forces in one direction. Moreover, such a probe has other geometric probe properties than conventional probes, which may be advantageous. An example of an embodiment is shown in FIGS. 14 and 15.

FIG. 14 shows the tip of a cantilever provided with a point-like projection, for example, formed in the same manner as the tip of ordinary AFM cantilevers.

The tip of the (111) cantilever may also be formed by a maskless immersion in an etching solution. In that case the geometry is as shown in FIG. 15. The 111 cantilever beam (indicated with dotted lines) may be provided with a sharp tip by short-etching without mask (by dipping). The etched cantilever is shown in the figure with full lines.

There is a need for ways of applying freestanding filaments in a reaction chamber or liquid channel. Freestanding refers to: not deposited on silicon or another heat conductor. An example is a flow sensor based on a heating filament. With the present technique of processing materials deposited on (111) oriented silicon substrates, it is possible to fabricate said freestanding filaments, for example, by depositing a conductor on a (111) membrane, applying a pattern and subsequently selectively etching away the Si membrane.

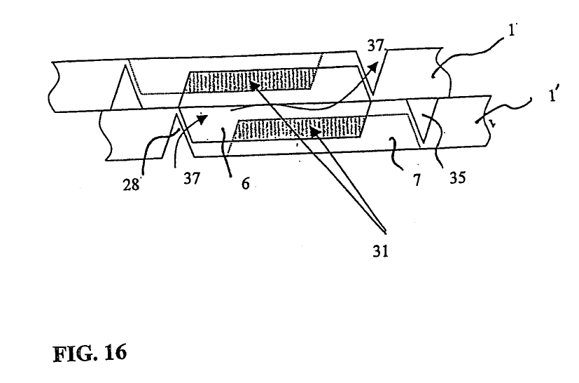

FIG. 16 finally shows a cross section of two wafers 1, 1′ as illustrated in FIG. 13. Here a continuous flow of fuel and oxidator is possible. Only one continuous flow path 36, indicated with arrow 37, of several flow paths is shown. The grey-shaded portions 31 are the active surfaces.

The invention is not limited to the above specifically described embodiments. It is limited only by the appended claims.

1. A method for the fabrication of a membrane oriented in a (111) plane of a (100) silicon wafer, comprising the steps of:
applying a masking layer to both sides of the wafer, wherein portions of the sides are covered by the masking layer; and
removing at least partially removal by etching away silicon material from the portions of the two sides of the wafer that are not covered,
wherein the etching step substantially removes the silicon material forming recesses in the two surfaces of the wafer, such that the walls of the recesses are formed by (111) planes,
wherein not covered portions at both sides of the wafer are aligned in relation to one another such that a (111) plane formed from a first side is oriented parallel to a (111) plane formed from a second side, and the distance d between said two planes is less than the thickness of the silicon wafer, so as to form a membrane in the (111) plane having a thickness d, and
wherein at least one through-opening is formed by an etching treatment in the membrane oriented in the (111) plane only, with the opening being oriented substantially perpendicularly in relation to the (111) plane.

2. A method according to claim 1, wherein into both sides of the wafer V-shaped recesses are etched, wherein the lowest point in a V-shaped recess in a first side is positioned adjacent to a not covered portion at the other side of the wafer.

3. A method according to claim 1, wherein a recess in a first side reaches up to the masking layer at the second side.

4. A method according to claim 1, wherein the thickness d is measured and the etching step is continued to etch the (111) planes until a desired thickness d is attained.

5. A method according to claim 1, wherein after the completion of the etching step, the masking layer is removed.

6. A method according to claim 1, wherein said step comprises providing a longitudinal opening that extends through the membrane formed in the (111) plane, wherein the opening extends from the free end of the membrane into the direction of a position where the membrane is attached to the wafer.

7. A method according to claim 1, wherein the through-opening is formed by an etching treatment, preferably by means of a dry-etching treatment, preferably a plasma etching treatment.

8. A method according to claim 1, wherein the through-opening is formed by radiation with a high-energy source.

9. A method according to claim 1, wherein at least two parallel longitudinal openings are formed, oriented substantially perpendicular in relation to the line where the formed membrane is attached to the wafer, so as to form at least one cantilever.

10. A membrane for orientation in a (111) plane of a (100) silicon wafer obtained by a method comprising the steps of:
applying a masking layer to both sides of the wafer, wherein portions of the sides are covered by the masking layer; and
removing at least partially by etching away silicon material from the portions of the two sides of the wafer that are not covered,
wherein the etching step substantially removes the silicon material forming recesses in the two surfaces of the wafer, such that the walls of the recesses are formed by (111) planes,
wherein not covered portions at both sides of the wafer are aligned in relation to one another such that a (111) plane formed from a first side is oriented parallel to a (111) plane formed from a second side, and the distance d between said two planes is less than the thickness of the silicon wafer, so as to form a membrane in the (111) plane having a thickness d, and
wherein at least one through-opening is formed by an etching treatment in the membrane oriented in the (111) plane only, with the opening being oriented substantially perpendicularly in relation to the (111) plane.

11. An application of a membrane according to claim 10 in a scanning element of a scanning element microscope, scanning probe microscope, or a friction force microscope.

12. An application of a membrane according to claim 10 in a mirror.

13. An application of a membrane according to claim 10, wherein a first surface of the (111) plane forms a reflecting surface and the other surface comprises a position-modifying means.

14. An application of a membrane according to claim 10 in a microgrip, by positioning two membranes in a V-shape such that their ends are oriented towards a mutual point of intersection and are placed at a distance from one another.

15. An application of a membrane according to claim 10 in a filter system, and provided with at least one opening.

16. An application according to claim 15, wherein at least one side of the wafer is covered with a mask, wherein the recesses formed at both sides of the membrane are in communication by means of the at least one opening.

17. An application of at least two membranes according to claim 10 arranged in a V-form in a positioning means, wherein at least one side of at least one of the membranes is provided with an actuator layer for actuating the at least one membrane, to allow an object on the membranes to be positioned in a predetermined manner.

18. An application of a membrane according to claim 10 in a microgripper as pick-and-place mechanism, for picking up objects to be handled, for manipulating and for moving them.

19. An application of a membrane according to claim 10, of which at least one surface is provided with a sensor layer, in a (bio) chemical sensor.

20. An application of a membrane according to claim 10 in a fuel cell, wherein on the membrane a first electrode is formed, electrically separated from a second electrode by an intermediate layer, and provided with openings to allow fuel to move from an outside of the first electrode to an outside of the second electrode.

21. An application according to claim 20, wherein the membrane is removed.

22. An application according to claim 20, wherein the intermediate layer is selected from the group comprising an electrolyte, for example, a solid oxide, a solid polymer, or a proton exchange membrane and a catalyst.

23. A method according to claim 1, wherein after the membrane has been formed with thickness d, a layer is applied of a material that exhibits a different etching behaviour than silicon, whereafter the silicon material is at least partly etched away.

24. A method according to claim 23, wherein the layer of the material is applied over at least a portion of the silicon membrane's surface.

25. A method according to claim 23, wherein the material forming the layer is selected from silicon nitride, silicon oxide or silicon carbide.

26. An application of a membrane obtained by the method according to claim 23, wherein the layer of the material is electrically conductive and has an elongated shape from a first connection point to a second connection point, and forms a heating element, and is connected at the two connecting points to a power source.
